(19) United States
(12) Patent Application Publication
(10) Pub. No.: US 2019/0219624 A1
(43) Pub. Date: Jul. 18, 2019

(54) BURIED GAS PIPELINE MULTI-MEASUREMENT DEVICE

(71) Applicant: Yeong-sang KONG, Gwangmyeong-si (KR)

(72) Inventor: Yeong-sang KONG, Gwangmyeong-si (KR)

(21) Appl. No.: 16/334,773

(22) PCT Filed: Aug. 22, 2017
(86) PCT No.: PCT/KR2017/009124

§ 371 Date: Mar. 20, 2019

(30) Foreign Application Priority Data
Sep. 27, 2016 (KR) 10-2016-0124020

(51) Int. Cl. G01R 29/12; G01N 17/02; G01R 31/02

(52) U.S. Cl. CPC G01R 29/12; G01R 31/025; G01N 17/02

(57) ABSTRACT

The present invention provides a buried gas pipeline multi-measurement device for identifying a gas pipeline among a plurality of pipelines, which are buried underground and have temporarily exposed parts, or identifying a protective potential measurement line for measuring the protective potential of the gas pipeline among a plurality of lines in a test box for measuring protective potential, or determining whether the protective potential measurement line has shorted, the device comprising both of: a current supply unit capable of supplying an on/off direct current to an exposed pipeline, which is exposed in the ground in a state in which exposed pipeline is directly connected to the gas pipeline; and an electric potential measurement unit capable of measuring the electric potential of each of the plurality of pipelines, which are buried underground and have temporarily exposed parts, or the electric potential of each of the plurality of lines in the test box for measuring protective potential, by means of the on/off direct current supplied by the current supply unit, wherein the current supply unit comprises a power source unit for generating a current and an interrupter for generating an on/off direct current by interrupting the current generated by the power source unit, and the power source unit comprises a built-in battery and/or an external battery for supplying a current. The buried gas pipeline multi-measurement device further comprises a microprocessor controller for controlling the current supply unit, the interrupter, and the power source unit.

### TECHNICAL FIELD

The present invention relates to a Buried gas pipeline multi-measurement device for identifying a Buried gas pipeline and testing safety or integrity of a corrosion-protective (abbrev. to ‘protective’) potential measurement line.

### BACKGROUND ART

A gas pipeline buried underground for transportation of, for example, liquefied natural gas is typically made of an iron-based metal member. The surface of a gas pipeline is coated with a synthetic resin such as polyalkylene ether in order to prevent degradation due to corrosion, and a cathodic protection technique is used to inhibit corrosion as a result of electrochemical reaction.

In general, cathodic protection equipment for preventing corrosion of various metal pipes adopts connection of a sacrificial anode more easily corroded than the pipe and the pipe using a wire, as well as a coating for insulating the pipe from soil so as to protect the pipe from corrosion or, otherwise, application of an external DC power supply to protect the pipe from corrosion.

FIG. 1 shows a gas pipeline buried underground and different lines connected to the gas pipeline.

With respect to the protection method using a sacrificial anode, an anode wire connected to the sacrificial anode passes through a test box and is directly connected to a gas pipeline P via a sacrificial pipeline 11. Owing to the sacrificial anode being more easily corroded than the gas pipeline P made of iron, corrosion of the gas pipeline P may be prevented. The sacrificial anode is usually fabricated using magnesium.

In the protection method using an external power supply, when direct current is supplied through a rectifier to an external power supply anode buried underground, the current passes through the ground and is transmitted to the gas pipeline P. The current transmitted to the gas pipeline P returns to the rectifier through a negative electrode connection line connected to a negative electrode of the external power supply to thus form a closed circuit. As such, the current is supplied to the gas pipeline P by the external power supply and thus prevents the corrosion of the gas pipeline P.

With regard to the protection method using a sacrificial anode or an external power supply, in order to identify whether a protective current flows properly to the gas pipeline P, a protective potential measurement line may be installed on the gas pipeline. Such a protective potential measurement line 10 is prepared by withdrawing an electric wire from the gas pipeline P with a current flow, then, connecting the same to a test box (T/B). A worker may measure a potential of the protective potential measurement line 10 for connecting the test box and the gas pipeline P and thus determine whether the protective current correctly flows in the gas pipeline P.

As seen in FIG. 1, the test box for measurement of protective potential may include a plurality of lines.

As described above, an anode wire, a sacrificial pipeline, a protective potential measurement line, etc. may be provided. In addition, some workers may install a false anode (FAKE ANODE) instead of the sacrificial anode, as an expedient, which may be withdrawn and placed in the test box. Optionally, in order to protect the gas pipeline P, a protective tube S is provided. Even in this case, a wire for anti-corrosion of the protective tube may be withdrawn and placed in the test box.

Sometimes, a worker needs to identify a protective potential measurement line among different wires and lines in the test box and determine whether the protective potential line is disconnected or not. FIG. 2 is an actual photograph of an example where there are plural lines in a test box. The worker should identify a protective potential measurement line among such plural lines and determine whether this line is disconnected or not.

However, workers on the ground cannot easily completely understand complex connection between the plural lines present underground on the basis of only the lines exposed above ground.

On the other hand, FIG. 3 is a photograph of plural pipes buried underground. As seen in FIG. 3, various pipes other than the gas pipeline may be present underground. Even in such case, the worker should sometimes check and identify the gas pipeline among such various pipes before proceeding with necessary action. The underground wherein the gas pipeline is buried may be dug up, however, this is a very expensive and inefficient task.

After a great deal of research and effort to develop a device capable of identifying a gas pipeline among different pipes buried underground and further testing integrity and/or safety of a protective potential measurement line connected to the gas pipeline by the inventors, the present invention has been completed.

### DISCLOSURE

### Technical Problem

An object of the present invention is to provide a multi-measurement device and a multi-measurement method of a gas pipeline buried underground, which can identify the gas pipeline among a plurality of pipes buried underground.

Further, another object of the present invention is to provide a multi-measurement device and a multi-measurement method of a gas pipeline buried underground, which can identify a protective potential measurement line among a plurality of lines received in a test box and determine whether or not the above measurement line was broken or disconnected.

On the other hand, other objects of the present invention not clarified herein will be further included within the scope of the present invention that can be easily deduced from the detailed description and effects thereof, as described below.

### Technical Solution

According to one embodiment of the present invention, there is provided a multi-measurement device of a buried gas pipeline (‘a Buried gas pipeline multi-measurement device’), capable of: identifying a gas pipeline among a plurality of pipes buried underground, a part of which is temporarily exposed above ground; identifying a protective potential measurement line to measure a protective potential of the gas pipeline among a plurality of lines placed in a test box for measurement of protective potential (‘a protective potential measurement test box’); and/or determining whether the protective potential measurement line is disconnected or not, wherein the multi-measurement device includes both of: a current supply unit which can supply On/Off direct current to a pipe exposed above ground while being directly connected to the gas pipeline; and a potential measurement unit capable of measuring a potential of each of the plural pipes buried underground, a part of which is temporarily exposed above ground, or a potential of each of the plural lines placed in the protective potential measurement test box, with the On/Off direct current supplied by the current supply unit, wherein the current supply unit includes: a power supply to generate a current; and an interrupter to interrupt the current generated by the power supply and generate On/Off direct current, wherein the power supply includes one or more of a built-in battery or an external battery to supply the current, and wherein the multi-measurement device further includes a microprocessor controller to control the current supply unit, the interrupter and the power supply.

The exposed pipe may include a district governor pipe, an area governor pipe or a gas shut-off valve.

According to another embodiment of the present invention, there is provided a Buried gas pipeline multi-measurement device, capable of: identifying a gas pipeline among a plurality of pipes buried underground, a part of which is temporarily exposed above ground; identifying a protective potential measurement line to measure a protective potential of the gas pipeline among a plurality of lines placed in a protective potential measurement test box; and/or determining whether the protective potential measurement line is disconnected or not, wherein the multi-measurement device includes both of: a current supply unit which can supply On/Off direct current to the protective potential measurement line in a first protective potential measurement test box, which was identified as being directly connected to the gas pipeline; and a potential measurement unit capable of measuring a potential of each of the plural pipes buried underground, a part of which is temporarily exposed above ground, or a potential of each of the plural lines placed in a second protective potential measurement test box, with the On/Off direct current supplied by the current supply unit, wherein the current supply unit includes: a power supply to generate a current; and an interrupter to interrupt the current generated by the power supply and generate On/Off direct current, wherein the power supply includes one or more of a built-in battery or an external battery to supply the current, and wherein the multi-measurement device further includes a microprocessor controller to control the current supply unit, the interrupter and the power supply.

### Advantageous Effects

Using the multi-measurement device and the multi-measurement method of buried gas pipelines according to the present invention, it is possible to identify a gas pipeline among different pipes buried underground without excavating the entire underground wherein the gas pipeline is buried.

Further, among plural lines received in a test box, a protective potential measurement line may be identified wherein the protective potential measurement line is provided to determine a current flow for protection of the gas pipeline. Further, it is possible to easily test whether or not the protective potential measurement line is disconnected.

On the other hand, it is further noted that, even though not explicitly mentioned herein, effects and/or possible effects stated in the following description which are expectable on the basis of technical features of the present invention may be considered to be equal to the specification of the present invention.

### DESCRIPTION OF DRAWINGS

FIG. 1 is a diagram illustrating a gas pipeline buried underground and various lines connected to the gas pipeline.

FIG. 2 is an actual photograph showing plural lines placed in a test box, while FIG. 3 is an actual photograph showing plural pipes buried underground after digging up a portion of the ground.

FIG. 4 is a configuration diagram illustrating a Buried gas pipeline multi-measurement device according to one embodiment of the present invention.

FIG. 5 is a diagram illustrating a method for identification of a gas pipeline according to one embodiment of the present invention.

FIG. 6 is a diagram illustrating a multi-measurement method of a protective potential measurement line according to one embodiment of the present invention.

FIG. 7 is a diagram illustrating a method for identification of a gas pipeline according to any embodiment of the present invention.

FIG. 8 is a diagram illustrating a multi-measurement method of a protective potential measurement line according to any embodiment of the present invention.

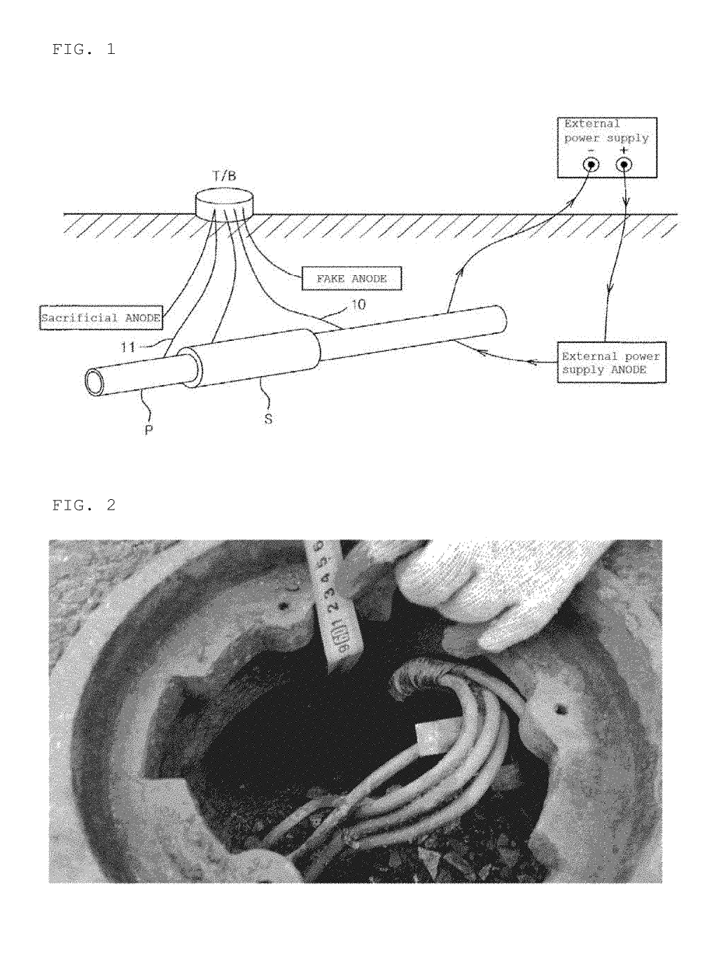

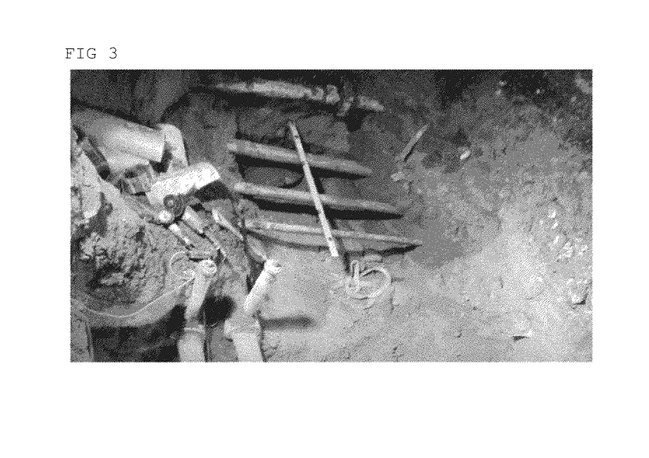

It is noted that the accompanying drawings are illustrated as a reference for understanding the technical spirit of the present invention, however, the scope of the present invention is not particularly limited thereto.

### BEST MODE

On the understanding that the present invention may include diverse modifications and a variety of embodiments, specific embodiments will be illustrated in the drawings and described in detail by the following description. However, this does not mean that the present invention is restricted to such specific embodiments, and it is to be understood that all of conversions, equivalents and/or substitutions included in the spirit and technical scope of the present invention are duly embraced. Further, if a concrete description of the related art in the specification of the present invention is considered to obscure the gist of the invention, a detailed description thereof will be omitted.

With respect to a first Buried gas pipeline multi-measurement device and a second Buried gas pipeline multi-measurement device, the terms ‘first’ and ‘second’ refer to indicate the same type of but multiple apparatuses.

The terms in the present specification are merely used to describe specific embodiments and are not intended to restrict the present invention. Expressions in singular number may also include a plural form unless context clearly indicates otherwise. In this application, the terms ‘include’ and ‘have’ are used to define the presence of features, numbers, steps, actions, components, parts or combinations thereof descried in the specification. However, the terms ‘include’ and ‘have’ are not intended to preclude the possible presence or addition of one or more other features, numbers, steps, actions, components, parts or combinations thereof.

Hereinafter, embodiments of the multi-measurement device and multi-measurement method of buried gas pipelines according to the present invention will be described in detail with reference to accompanying drawings. In the following description with reference to the accompanying drawings, the same or corresponding components are defined by the same numerals and redundant explanation thereof will be omitted.

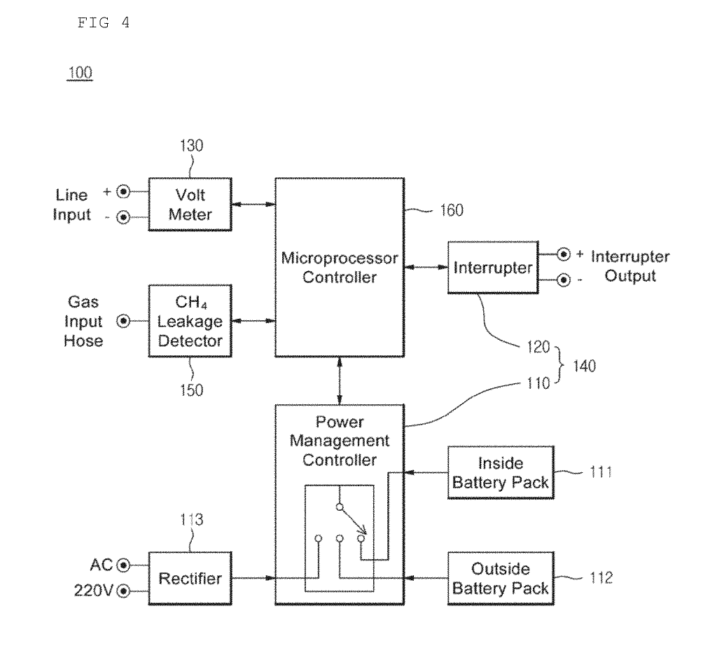

FIG. 4 is a configuration diagram illustrating a Buried gas pipeline multi-measurement device according to one embodiment of the present invention.

Referring to FIG. 4, the Buried gas pipeline multi-measurement device 100 of the present invention may: identify a gas pipeline among a plurality of pipes buried underground, a part of which is temporarily exposed above ground; identify a protective potential measurement line to measure a protective potential of the gas pipeline among a plurality of lines placed in a protective potential measurement test box; and/or determine whether the protective potential measurement line is disconnected or not, wherein the multi-measurement device includes both of a current supply unit 140 and a potential measurement unit 130. In order to identify the gas pipeline or the protective potential measurement line or to determine whether the protective potential measurement line is disconnected or not using the device of the present invention, a pair of the Buried gas pipeline multi-measurement devices 100 is required.

That is, a pair of the same devices, each having both of the current supply unit 140 and the potential measurement unit 130, may be used to supply the current by the one device while measuring the potential by the other.

According to the present invention, a single device has both of the current supply unit 140 and the potential measurement unit 130, and therefore, it is possible to prevent electricity-related human error or accidents in the field possibly occurring when conventional manufacturer-specific devices are connected respectively to determine safety or integrity of the test box. Further, separate devices having large load and volume may be connected respectively to determine the integrity of the test box, thereby solving conventional problems such a great deal of time and manpower allocation for preparation of diagnostic conditions.

The current supply unit 140 is connected directly to the gas pipeline while supplying On/Off DC to a pipe exposed above ground. In this case, the exposed pipe selected as a point at which the current is fed, means a pipe identified to be directly connected to the gas pipeline. Therefore, it is obviously understood that the current fed to the exposed pipe would be supplied to the gas pipeline buried underground.

The exposed pipe may include a district governor pipe, an area governor pipe, a gas shut-off valve, or the like.

As shown in FIG. 4, the current supply unit 140 may include a power supply 110 and an interrupter 120. The power supply 110 may include any one of a built-in battery 111, an external battery 112, and a rectifier 113 to switch external alternating current (AC) power into direct current.

Using the built-in battery 111 or the external battery 112 may allow easy portability of the device. The worker generally proceeds a test using the test box while moving and, if using such a battery as described above, can conduct work much more easily and simply.

Other than the batteries, a rectifier 113 may be further included to instantly utilize the surrounding external power supply as a power source. The rectifier 113 may switch AC power generated in the surroundings into direct current.

The interrupter 120 may interrupt the current generated by the power supply 110 and generate On/Off direct current. The reason for using the On/Off direct current in the present invention instead of On current is described below.

If holding on the On current, there are problems as follows. A current generated in a subway, a power system, a telecommunication system, etc. and a current for a gas pipeline typically generate mutual interference. That is, since the current already flows over the pipes, a number of errors may be caused in finding a protective potential measurement line or any desired pipe if On current is supplied on the ground.

Accordingly, existing interferential current may cause periodic or intermittent interference with a protective current of the gas pipeline. Therefore, the present invention is designed to find a desired gas pipeline or protective potential measurement line by applying On/Off current at a predetermined interval instead of On current.

The Buried gas pipeline multi-measurement device 100 of the present invention may further include a microprocessor controller 160 in addition to the potential measurement unit 130 and the current supply unit 140. The microprocessor controller 160 serves to control overall operation of the device and, in particular, may control the interrupter 120, the current supply unit 140, the power supply 110, etc.

In addition, the Buried gas pipeline multi-measurement device 100 of the present invention may further include a methane (CH₄) leakage detector 150. A gas leakage alarm system may be designed to be operated at a concentration of one-quarter (¼) or less (1.25% or less in the air) of the explosion lower limit value, thereby guarding against accidents.

FIGS. 5 to 8 are diagrams illustrating a method for identification of a gas pipeline and a multi-measurement method of a protective potential measurement line by means of the Buried gas pipeline multi-measurement device 100 according to the present invention.

In particular, FIG. 5 illustrates a gas pipeline identification method according to one embodiment of the present invention.

During a construction schedule or operation, different pipes including the gas pipeline buried underground may be partially exposed.

Herein, the gas pipeline should be identified. In this case, a first Buried gas pipeline multi-measurement device 100 may supply On/Off current to the exposed pipe (e.g., a governor). At this time, a line 121 withdrawn from an interrupter 120 of the first Buried gas pipeline multi-measurement device 100 is electrically connected to the exposed pipe (the governor) to thus supply On/Off current.

The On/Off current supplied from the interrupter 120 to the gas pipeline through the governor may allow identification of the gas pipeline among a plurality of pipes. That is, a line 131 is withdrawn from the potential measurement unit 130 in a second Buried gas pipeline multi-measurement device 100 and then is connected to each of the plural pipes and, when a potential of each of the plural pipes is measured, the pipe in which On/Off potential is measured can be determined as the gas pipeline. The above task needs at least two workers, one of whom may supply On/Off current using the first Buried gas pipeline multi-measurement device 100 while the other should use the second Buried gas pipeline multi-measurement device 100 and measure the potential in the plural pipes partially exposed above ground.

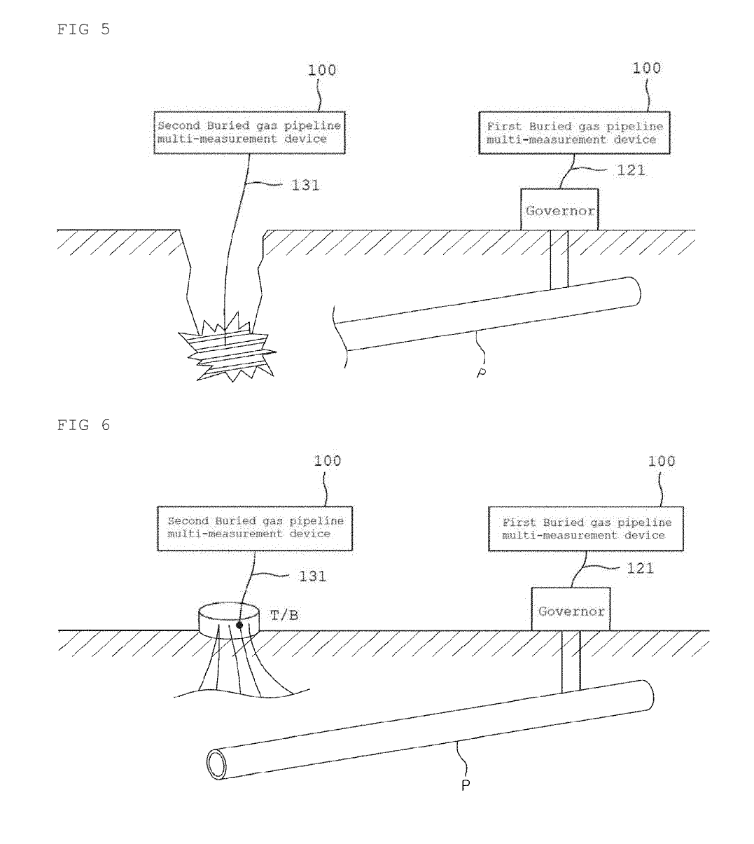

FIG. 6 is a diagram illustrating a multi-measurement method of a protective potential measurement line according to the present invention.

Similar to FIG. 5, in order to perform the present operation, at least two workers and at least two Buried gas pipeline multi-measurement devices 100 are required.

When a first worker uses the first Buried gas pipeline multi-measurement device 100 and supplies On/Off current to a governor, a second worker may measure a potential of each of plural lines placed in a test box using the second Buried gas pipeline multi-measurement device 100.

The line, On/Off potential of which has been identified, may be determined as a protective potential measurement line and, in this case, it can be determined that the protective potential measurement line is normally and safely connected to the gas pipeline without breakage.

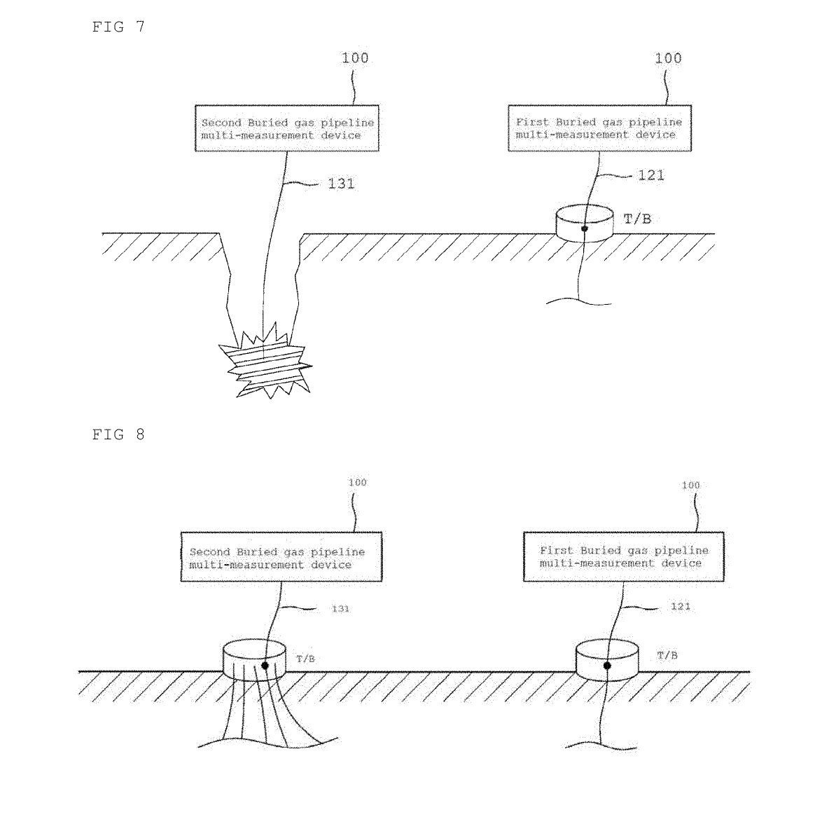

FIG. 7 is a diagram illustrating a gas pipeline identification method according to any embodiment of the present invention, while FIG. 8 is a diagram illustrating a multi-measurement method of a protective potential measurement line according to any embodiment of the present invention.

A difference between FIG. 7 and FIG. 5 is that a current feeding point by the first Buried gas pipeline multi-measurement device 100 in FIG. 7 is not the exposed pipe but the protective potential measurement line which was identified as being connected to the gas pipeline in the test box. That is, the others except for the difference in current feeding point are substantially the same as shown in FIG. 5, therefore, a detailed description thereof will be omitted.

Likewise, FIG. 8 is substantially the same as shown in FIG. 6 except for the difference in current feeding point. That is, the current feeding point is not the exposed pipe but the protective potential measurement line which was identified as being connected to the gas pipeline in the test box to receive On/Off current.

Hereinafter, an example of a method for determining integrity inside the test box using the Buried gas pipeline multi-measurement device 100 according to one embodiment of the present invention will be described in detail.

In order to investigate whether the protective potential measurement line in the whole test box is safely connected to the gas pipeline buried underground, an electric contact point is formed on a pipe exposed above ground wherein the pipe is a portion of a pipe insulating flange at an underground entrance point, and then, On/Off current is supplied through the current supply unit 140 of the first Buried gas pipeline multi-measurement device 100 according to the present invention. Herein, the interrupter 120 in the current supply unit 140 may supply the On/Off current at a predetermined interval while interrupting the current.

Each of the plural lines in the test box is subjected to potential measurement using the second Buried gas pipeline multi-measurement device 100 according to the present invention. The potential measurement may be performed using the potential measurement unit 130 in the second Buried gas pipeline multi-measurement device 100 as well as a saturated copper sulfate (Cu/CuSO₄) reference electrode (CSE).

Through the first Buried gas pipeline multi-measurement device 100, On/Off current is supplied to the exposed pipe or the protective potential measurement line which was identified as being connected to the gas pipeline. On the other hand, On/Off potential difference between the plural lines placed in the test box is examined using the second Buried gas pipeline multi-measurement device 100. Under the above conditions, if On/Off potential difference is observed at some lines in the test box, the lines may be determined as the protective potential measurement lines directly connected to the gas pipeline. Further, it can also be determined that the protective potential measurement lines were safely connected to the gas pipeline without breakage.

Consequently, use of the Buried gas pipeline multi-measurement device 100 of the present invention may ensure very simple portability and use of the device, prevention of gas accident, enhanced preventive action and integrity of a gas pipeline under long-term use.

The scope of the present invention is not particularly limited to the embodiments explicitly described and represented above. Further, it is noted again that the scope of the present invention is not limited by alterations and/or substitutions obviously known in the technical field to which the present invention pertains.
100: Buried gas pipeline multi-measurement device
110: Power supply
111: Built-in battery
112: External battery
113: Rectifier
120: Interrupter
130: Potential measurement unit
140: Current supply unit
150: Methane leakage detector
160: Microprocessor controller

What is claimed is:

1. A multi-measurement device of a buried gas pipeline (‘a Buried gas pipeline multi-measurement device’), with functions of: identifying a gas pipeline among a plurality of pipes buried underground, a part of which is temporarily exposed above ground; identifying a protective potential measurement line to measure a protective potential of the gas pipeline among a plurality of lines placed in a test box for measurement of protective potential (‘a protective potential measurement test box’); and/or determining whether the protective potential measurement line is disconnected or not, comprising both of:
a current supply unit which can supply On/Off direct current to a pipe exposed above ground while being directly connected to the gas pipeline; and
a potential measurement unit capable of measuring a potential of each of the plural pipes buried underground, a part of which is temporarily exposed above ground, or a potential of each of the plural lines placed in the protective potential measurement test box, with the On/Off direct current supplied by the current supply unit,
wherein the current supply unit includes:
a power supply to generate a current; and
an interrupter to interrupt the current generated by the power supply and generate On/Off direct current,
wherein the power supply includes one or more of a built-in battery and an external battery to supply the current, and
wherein the multi-measurement device further includes a microprocessor controller to control the current supply unit, the interrupter and the power supply.

2. The device according to claim 1, wherein the exposed pipe includes a district governor pipe, an area governor pipe or a gas shut-off valve.

3. A Buried gas pipeline multi-measurement device, with functions of: identifying a gas pipeline among a plurality of pipes buried underground, a part of which is temporarily exposed above ground; identifying a protective potential measurement line to measure a protective potential of the gas pipeline among a plurality of lines placed in a protective potential measurement test box; and/or determining whether the protective potential measurement line is disconnected or not, comprising both of:
a current supply unit which can supply On/Off direct current to the protective potential measurement line in a first protective potential measurement test box, which was identified as being directly connected to the gas pipeline; and
a potential measurement unit capable of measuring a potential of each of the plural pipes buried underground, a part of which is temporarily exposed above ground, or a potential of each of the plural lines placed in a second protective potential measurement test box, with the On/Off direct current supplied by the current supply unit,
wherein the current supply unit includes:
a power supply to generate a current; and
an interrupter to interrupt the current generated by the power supply and generate On/Off direct current,
wherein the power supply includes:
one or more of a built-in battery and an external battery to supply the current, and
wherein the multi-measurement device further includes a microprocessor controller to control the current supply unit, the interrupter and the power supply.
